(19) United States
(12) Patent Application Publication
(10) Pub. No.: US 2024/0036093 A1
(43) Pub. Date: Feb. 1, 2024

(54) APPARATUS FOR MEASURING CHARACTERISTICS OF CAPACITOR COMPONENT

(71) Applicant: SAMSUNG ELECTRO-MECHANICS CO., LTD., Suwon-si (KR)

(72) Inventors: Se Joo Kim, Suwon-si (KR); Seung Won Park, Suwon-si (KR); Hee Sun Han, Suwon-si (KR); Yong Hoon Kim, Suwon-si (KR); Sang Jin Park, Suwon-si (KR)

(73) Assignee: SAMSUNG ELECTRO-MECHANICS CO., LTD., Suwon-si (KR)

(21) Appl. No.: 18/220,509

(22) Filed: Jul. 11, 2023

(30) Foreign Application Priority Data
Aug. 1, 2022 (KR) 10-2022-0095485

(51) Int. Cl. G01R 27/26

(52) U.S. Cl. CPC G01R 27/2605; G01R 27/2611

(57) ABSTRACT

An apparatus for measuring characteristics of a capacitor component includes a measurement terminal connected to a capacitor component, an inductor connected to the measurement terminal, and a controller generating characteristic information of the capacitor component based on LC resonance of the capacitor component and the inductor. The controller generates capacitance information of the capacitor component based on inductance, based on at least one of a resonant frequency and an amplitude of the LC resonance and the resonant frequency.

### CROSS-REFERENCE TO RELATED APPLICATION

This application claims benefit of priority to Korean Patent Application No. 10-2022-0095485 filed on Aug. 1, 2022 in the Korean Intellectual Property Office, the disclosure of which is incorporated herein by reference in its entirety.

### TECHNICAL FIELD

The present disclosure relates to an apparatus for measuring characteristics of a capacitor component.

### BACKGROUND

Recently, as demand for electronic devices and electric devices (including vehicles) has rapidly increased according to the 4th industrial revolution, demand for capacitor components used in electronic devices/electric devices has also rapidly increased.

Therefore, the number of transactions of capacitor components between electronic device/electrical device manufacturers and capacitor component manufacturers has rapidly increased, and efficiency and convenience of measuring characteristics of capacitor components, which is important information in the capacitor component trading process, have become increasingly important.

In addition, as the services provided by electronic devices/electrical devices have become increasingly complex, performance required of electronic devices/electrical devices has gradually increased, accuracy/precision of the characteristics of capacitor components has also been increasingly required, and various types of capacitor components having different characteristics have been manufactured. As the types of capacitor components vary, difficulty (versatility) of securing accuracy/precision in characteristics of capacitor components may increase.

Consequently, performance of an apparatus for measuring characteristics of capacitor components may be evaluated based on the efficiency, convenience, accuracy, precision, and versatility of measuring characteristics of capacitor components, and the performance of the device is becoming increasingly important.

### SUMMARY

An aspect of the present disclosure may provide an apparatus for measuring characteristics of a capacitor component, capable of improving performance (at least one of efficiency, convenience, accuracy, precision, and versatility) for measurement of capacitor component characteristics.

According to an aspect of the present disclosure, an apparatus for measuring characteristics of a capacitor component may include a measurement terminal connected to a capacitor component, an inductor connected to the measurement terminal, and a controller generating characteristic information of the capacitor component based on LC resonance of the capacitor component and the inductor. The controller generates capacitance information of the capacitor component based on inductance, dependent on at least one of a resonant frequency and an amplitude of the LC resonance and the resonant frequency.

According to another aspect of the present disclosure, an apparatus for measuring characteristics of a capacitor component may include a measurement terminal connected to the capacitor component, an inductor connected to the measurement terminal, a controller generating characteristic information of the capacitor component based on the LC resonance of the capacitor component and the inductor, and a regulator feeding back the LC resonance so that the amplitude of the LC resonance approaches a target amplitude.

According to an aspect of the present disclosure, a method for measuring characteristics of a capacitor component may include obtaining LC resonance of the capacitor component and an inductor connected to the capacitor component in a measurement circuit; obtaining an amplitude of the LC resonance and obtaining a resonant frequency of the LC resonance; determining a range of a root mean square (RMS) voltage based on a measured value of the amplitude of the LC resonance; determining inductance corresponding to the resonant frequency of inductance characteristics corresponding to the range of the RMS voltage; and determining capacitance information based on the determined inductance.

According to an aspect of the present disclosure, an apparatus for measuring characteristics of a capacitor component may include a processor; and a non-transitory computer readable medium storing an algorithm, when executed by the processor, to cause the processor to: obtain LC resonance of the capacitor component and an inductor connected to the capacitor component in a measurement circuit, obtain an amplitude of the LC resonance and obtain a resonant frequency of the LC resonance, determine a range of a root mean square (RMS) voltage based on a measured value of the amplitude of the LC resonance, determine inductance corresponding to the resonant frequency of inductance characteristics corresponding to the range of the RMS voltage, and determine capacitance information based on the determined inductance.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a circuit diagram illustrating an apparatus for measuring characteristics of a capacitor component according to an exemplary embodiment in the present disclosure;

FIG. 2 is a block diagram illustrating an apparatus for measuring characteristics of a capacitor component according to an exemplary embodiment in the present disclosure;

FIG. 3A is a flowchart illustrating an operation of a controller of an apparatus for measuring characteristics of a capacitor component according to an exemplary embodiment in the present disclosure;

FIG. 3B is a graph illustrating inductance characteristics of an inductor of an apparatus for measuring characteristics of a capacitor component according to an exemplary embodiment in the present disclosure;

FIG. 3C is a graph illustrating division of one of the inductance characteristics of FIG. 3B into a plurality of resonant frequency ranges;

FIGS. 3D through 3H are graphs illustrating inductance characteristics for each of a plurality of resonant frequency ranges of FIG. 3C and approximation thereof by a polynomial;

FIG. 31 is a graph illustrating inductance characteristics changing as an amplitude of LC resonance is lowered;

FIG. 4 is a circuit diagram illustrating a variable DC voltage provider of an apparatus for measuring characteristics of a capacitor component according to an exemplary embodiment in the present disclosure;

FIG. 5 is a circuit diagram illustrating a regulator of an apparatus for measuring characteristics of a capacitor component according to an exemplary embodiment in the present disclosure;

FIG. 6 is a circuit diagram illustrating a waveform converter of an apparatus for measuring characteristics of a capacitor component according to an exemplary embodiment in the present disclosure; and

FIG. 7 is a diagram illustrating a portable appearance of an apparatus for measuring characteristics of a capacitor component according to an exemplary embodiment in the present disclosure.

### DETAILED DESCRIPTION

Exemplary embodiments of the present disclosure will now be described in detail with reference to the accompanying drawings.

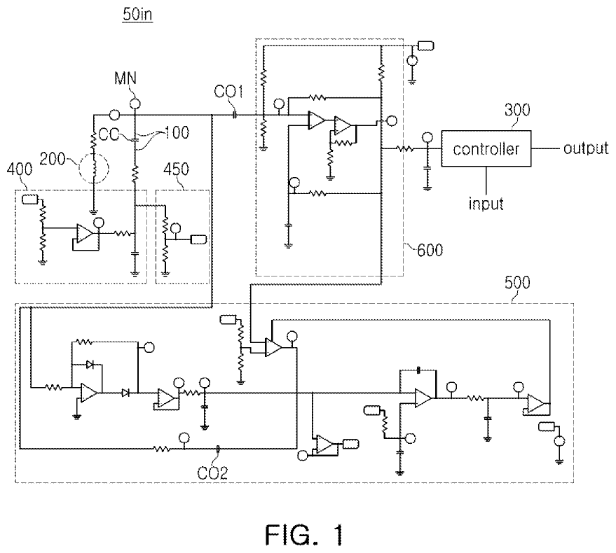

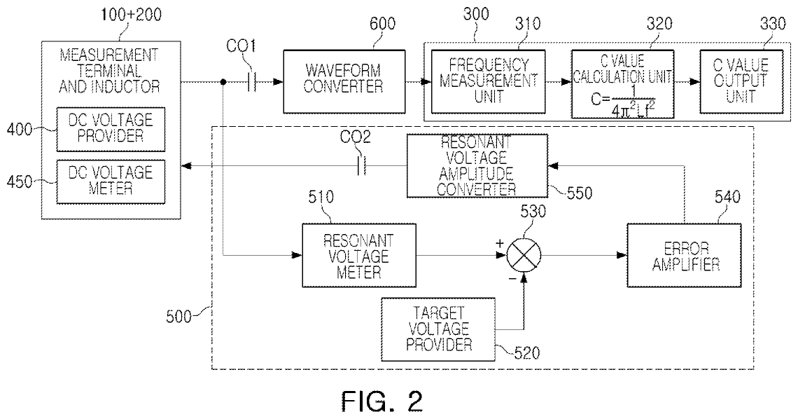

Referring to FIGS. 1 and 2, an apparatus 50in for measuring characteristics of a capacitor component according to an exemplary embodiment in the present disclosure may include a measurement terminal 100, an inductor 200, and a controller 300, and measure characteristics (e.g., capacitance, capacitance according to a DC voltage, capacitance according to an amplitude of an AC voltage, capacitance according to a frequency of an AC voltage) of a capacitor component CC.

The measurement terminal 100 may be connected to the capacitor component CC. For example, the measurement terminal 100 may include a probe and may be connected to a cable. Accordingly, a user may measure the capacitor component CC by contacting the measurement terminal 100 to an external electrode of the capacitor component CC. Alternatively, the measurement terminal 100 may be in the form of a pin that is fixedly disposed on a printed circuit board (PCB) and exposed externally, and the user may measure the capacitor component CC by placing the capacitor component CC on the pin.

The inductor 200 may be electrically connected to the measurement terminal 100. For example, the inductor 200 may be a coil component and may be pre-mounted on a PCB. Alternatively, the inductor 200 may have a structure in which wires of a PCB are formed in a coil shape, instead of a coil component.

The controller 300 may be configured to generate characteristic information of the capacitor component CC based on LC resonance of the capacitor component CC and the inductor 200. Impedance in a combination structure of the capacitor component CC and the inductor 200 may vary according to frequency, and may be a minimum value (in the case of LC series resonance) or a maximum value (in the case of LC parallel resonance) at a resonant frequency of the LC resonance. In circuit theory, the square of the resonant frequency may be [1/{(inductance)*(capacitance)*4*(pi)*(pi)}]. The controller 300 may obtain all of the remaining information except for the capacitance, and may generate characteristic information corresponding to the capacitance based on the remaining information.

Therefore, since a structure required to obtain characteristic information corresponding to the capacitance based on the LC resonance may be simplified, the apparatus for measuring characteristics of a capacitor component according to an exemplary embodiment in the present disclosure may be advantageously implemented as a portable apparatus, like an apparatus 50out for measuring characteristics of a capacitor component illustrated in FIG. 7 and may be advantageous for improving efficiency/convenience, among performance of measuring characteristics of a capacitor component.

Since the minimum and maximum values of the impedance may be close to 0 and infinity, respectively, a change rate of impedance near the resonant frequency may be large according to a change in the resonant frequency. Therefore, compared to RC resonance, accuracy/precision of measuring characteristic information corresponding to capacitance based on the LC resonance may be relatively higher.

Therefore, the apparatus 50in for measuring characteristics of a capacitor component according to an exemplary embodiment in the present disclosure may be advantageous in increasing accuracy/precision among performance of measuring characteristics of a capacitor component.

The capacitor component CC may be a multilayer ceramic capacitor (MLCC), but is not limited thereto. The capacitance of the capacitor component CC may vary depending on the type of capacitor component CC. For example, the range of capacitance of the MLCC may be approximately 1 nF to 47 μF, which may be a wide range.

In general, as the efficiency/convenience and accuracy/precision of an apparatus for measuring capacitance is higher, the capacitance measurement range may be limited. Even if the apparatus provides a wide capacitance measurement range, accuracy/precision in a portion of the wide capacitance measurement range may be low.

Assuming that inductance is a constant, the resonant frequency of the LC resonance may vary as the capacitance of the capacitor component CC changes. Since the inductance of the actual inductor 200 may be slightly dependent on the resonant frequency or amplitude of the LC resonance due to the characteristics of a magnetic material or metal material of the inductor 200, the resonant frequency may primarily actually change depending on the change in capacitance of the capacitor component CC and may secondarily change according to a change in the inductance of the inductor 200 as well. In addition, due to physical characteristics of the LC resonance, the amplitude of LC resonance may also change according to a change in the resonant frequency of the LC resonance.

The controller 300 may generate capacitance information of the capacitor component CC based on the inductance and the resonant frequency dependent on at least one of the resonant frequency and the amplitude of the LC resonance. Therefore, since the controller 300 may calculate the capacitance using the inductance determined more accurately in consideration of the resonant frequency or amplitude of the LC resonance, the capacitance information of the capacitor component CC may be more accurately generated.

Accordingly, the apparatus 50in for measuring characteristics of a capacitor component according to an exemplary embodiment in the present disclosure is advantageous in increasing the efficiency/convenience and accuracy/precision of measurement performance, while stably securing measurement accuracy/precision in a wide capacitance range of the capacitor component CC.

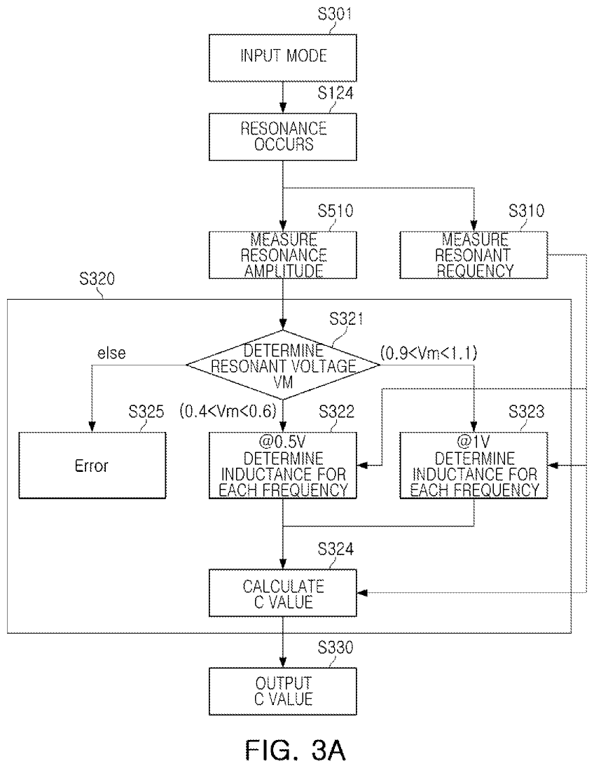

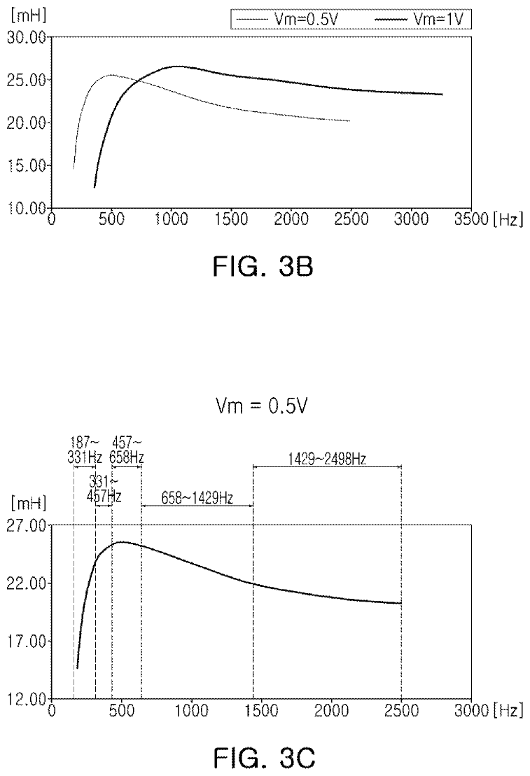

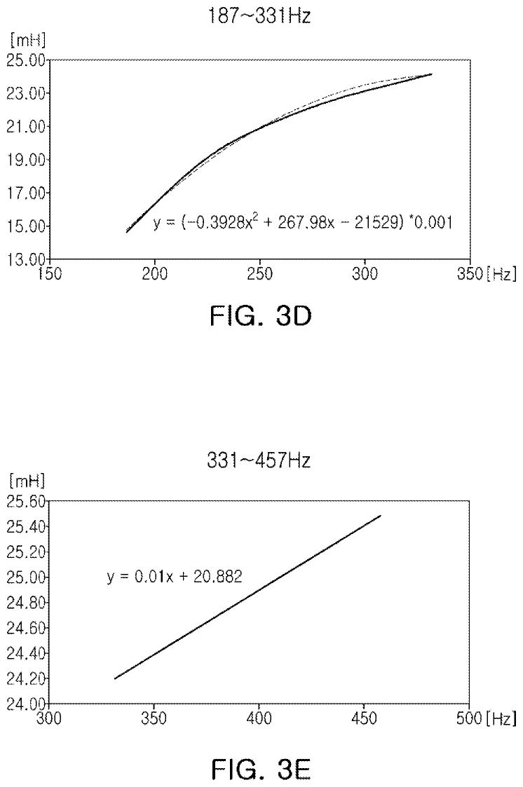

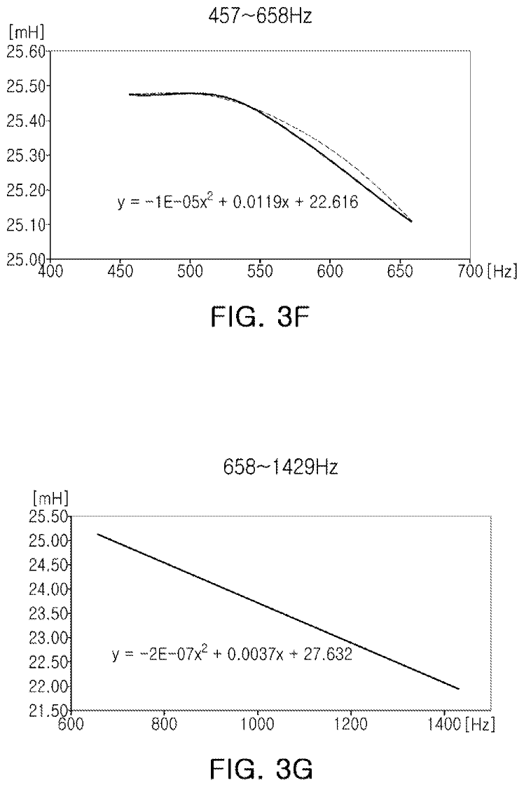

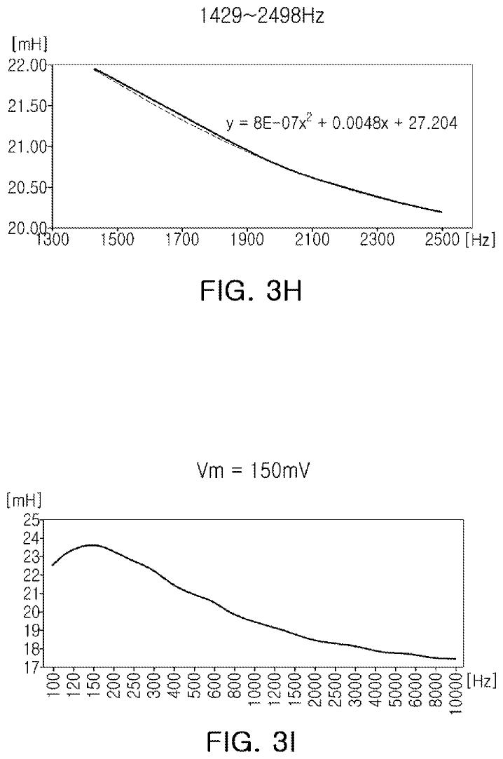

Referring to FIGS. 2 and 3A, a frequency measurement unit 310 of the controller 300 may measure the amplitude of the LC resonance (S510) or measure the resonant frequency (S310) when the LC resonance of the capacitor component and the inductor occurs (S124). A C value calculation unit 320 of the controller 300 may calculate the capacitance information (C value) of the capacitor component CC based on at least one of the resonant frequency and the amplitude of the LC resonance (S320), and a C value output unit 330 of the controller 300 may output the calculated capacitance information (output) (S330).

For example, the controller 300 may be configured as an embedded system, and may include a micro controller unit (MCU) or a processor, and a non-transitory computer readable medium storing an algorithm corresponding to the flowchart of FIG. 3A. When the algorithm is executed by the micro controller unit (MCU), the processor, or the controller 300, the micro controller unit (MCU), the processor, or the controller 300 may be configured to perform operations shown in the flowchart of FIG. 3A. Depending on the design, the controller 300 may collect voltage value information or current value information of a plurality of nodes MN of the apparatus 50in for measuring characteristics of a capacitor component and may use the collected information to generally control or manage the apparatus 50in for measuring characteristics of a capacitor component.

The horizontal axis and the vertical axis of FIG. 3B represent the resonant frequency of the LC resonance and the inductance of the inductor, respectively, and the two curves in FIG. 3B represent inductance characteristics according to resonant frequencies when root mean square (RMS) voltages Vm of the LC resonance are 0.5 V and 1 V, respectively. Referring to FIG. 3B, the inductance of the inductor may be dependent on the resonant frequency or amplitude of the LC resonance, and a rate of change of the inductance according to a change in the resonant frequency of the LC resonance may vary depending on the resonant frequency. The fact that the rate of change varies according to the resonant frequency may mean that the inductance characteristic is nonlinear.

For example, referring to FIG. 3A, the controller 300 may determine whether the RMS voltage Vm of the LC resonance generated based on the measured value of the amplitude of the LC resonance falls within a first RMS voltage range of V to 0.6 V or falls within a second RMS voltage range of V to 1.1 V (S321). Thereafter, according to a determination result, the controller 300 may determine the inductance corresponding to the resonant frequency of the inductance characteristics corresponding to the first RMS voltage range (S322) or determine the inductance corresponding to the resonant frequency of the inductance characteristics corresponding to the second RMS voltage range (S323), and when the RMS voltage Vm of the LC resonance does not fall within a predetermined RMS voltage range, the controller 300 may determine that it is an error (S325). In the case of the error, the controller 300 may set a waiting time, and during the waiting time, the controller 300 may further adjust the RMS voltage Vm of the LC resonance. Thereafter, the controller 300 may calculate capacitance information (C value) using the determined inductance (S324). FIG. 3A illustrates that the number of RMS voltage ranges is two and a width of the RMS voltage range is constant, but the number and width of the RMS voltage range are not particularly limited.

Depending on the design, the controller may receive mode information (input) before LC resonance occurs (S301), and may determine inductance using inductance characteristics corresponding to an RMS voltage range determined according to the mode information. For example, the mode information may be generated by user input.

For example, as the capacitance of the capacitor component CC increases, an optimum value of the RMS voltage Vm of the LC resonance for measuring the characteristics of the capacitor component CC may decrease. For example, the optimum value may be 1 V when the capacitance of the capacitor component CC is 10 μF or less, and may be 0.5 V when the capacitance of the capacitor component CC exceeds 10 μF. A user may input the mode information according to the capacitance of the capacitor component CC.

For example, when the capacitor component CC is a multilayer ceramic capacitor (MLCC), the optimum value of the RMS voltage Vm of the LC resonance may vary depending on the characteristics (e.g., a difference in the composition ratio of a barium titanate composition) of a ferroelectric material of the capacitor component CC, and thus, the user may input the mode information according to the characteristics of the ferroelectric material of the capacitor component CC.

Referring to FIG. 3C, one of the inductance characteristics of FIG. 3B may be divided into a plurality of inductance characteristics corresponding to a plurality of resonant frequency ranges. FIG. 3C illustrates five resonant frequency ranges, but the number of resonant frequency ranges is not particularly limited.

The solid lines in FIGS. 3D to 3H represent a portion of one of the inductance characteristics of FIG. 3B, and the dotted lines in FIGS. 3D to 3H represent curves corresponding to polynomials having characteristics similar to the inductance characteristics. In the polynomial, X and Y may respectively correspond to values of the horizontal axis and the vertical axis.

Referring to FIGS. 3D to 3H, the inductance characteristics of FIG. 3C include a first inductance characteristic corresponding to a first resonant frequency range (187 to 331 Hz), a second inductance characteristic corresponding to a second resonant frequency range (331 to 457 Hz), a third inductance characteristic corresponding to a third resonant frequency range (457 to 658 Hz), a fourth inductance characteristic corresponding to a fourth resonant frequency range (658 to 1429 Hz), and a fifth inductance characteristic corresponding to a fifth resonant frequency range (1429 to 2498 Hz). Therefore, the controller 300 may generate capacitance information based on the inductance according to an inductance determination method (e.g., a predetermined polynomial) corresponding to the resonant frequency range to which the resonant frequency of the LC resonance belongs, among a plurality of predetermined resonant frequency ranges, and the resonant frequency.

Coefficients of the X variables of the first, second, third, fourth, and fifth polynomials corresponding to the first, second, third, fourth, and fifth inductance characteristics may be different from each other. Therefore, sensitivity of the resonant frequency of the inductance determination method may vary according to a resonant frequency range to which the resonant frequency of the LC resonance belongs, among the plurality of resonant frequency ranges.

Depending on the design, each of the first, second, third, fourth and fifth inductance characteristics may be simplified to an inductance constant. Accordingly, the controller 300 may generate capacitance information based on the inductance constant corresponding to the resonant frequency range to which the resonant frequency of the LC resonance belongs, among the plurality of resonant frequency ranges, and the resonant frequency of the LC resonance.

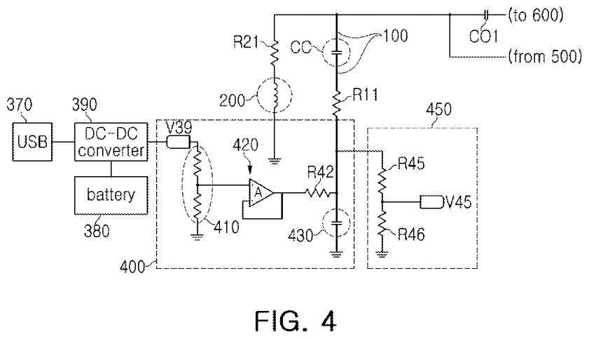

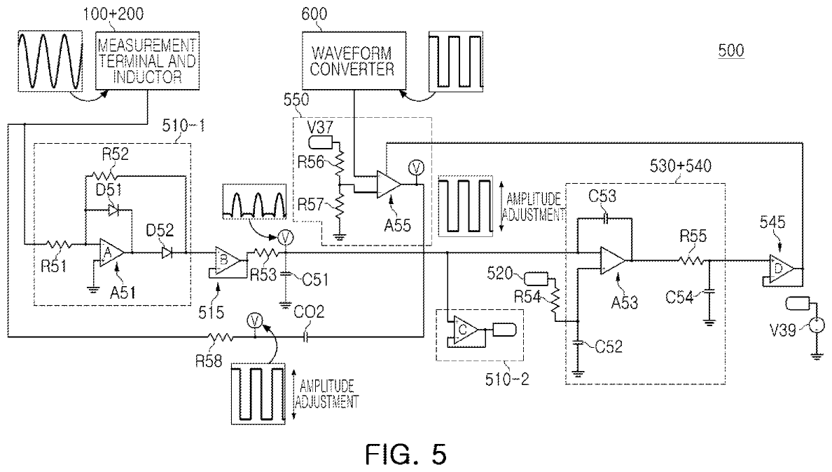

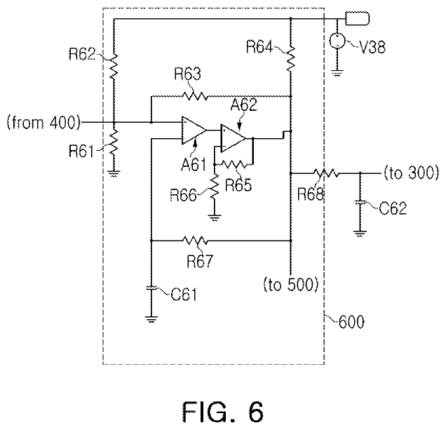

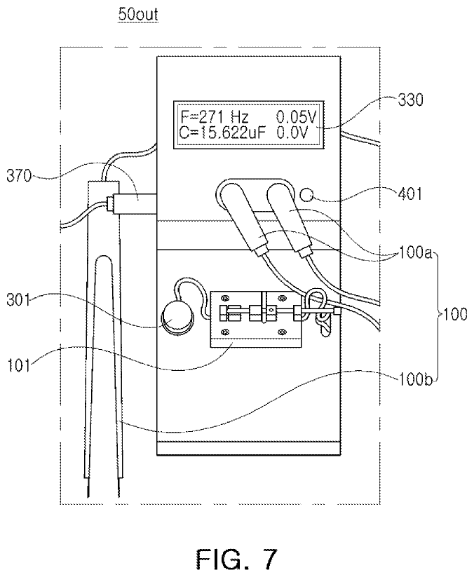

Referring to FIG. 31, inductance characteristics when the RMS voltage Vm of the LC resonance is 150 mV may be different from the inductance characteristics of FIG. 3B.

Meanwhile, referring to FIGS. 1 and 2, the apparatus for measuring characteristics of a capacitor component according to an exemplary embodiment in the present disclosure may further include a regulator 500 feeding back the LC resonance so that the amplitude of the LC resonance is close to a target amplitude.

Accordingly, a change in the amplitude of the LC resonance due to a change in the capacitance of the capacitor component CC or a change in the resonant frequency of the LC resonance may be suppressed. Therefore, since one (the amplitude) of two variables (the resonant frequency and the amplitude) that may affect the inductance of the inductor 200 may be removed, the accuracy of the inductance of the inductor 200 may be effectively increased.

Accordingly, the apparatus 50in for measuring characteristics of a capacitor component according to an exemplary embodiment in the present disclosure may be advantageous in increasing the efficiency/convenience and accuracy/precision of measurement performance, while stably securing measurement accuracy/precision in a wide capacitance range of the capacitor component CC.

Referring to FIGS. 1, 2 and 5, the regulator 500 of the apparatus 50in for measuring characteristics of a capacitor component according to an exemplary embodiment in the present disclosure may include at least one of a resonant voltage meter 510, a target voltage provider 520, a comparator 530, an error amplifier 540, and a resonant voltage amplitude converter 550.

The resonant voltage meter 510 may have an input terminal electrically connected to at least one of the measurement terminal 100 and the inductor 200, and may rectify an input signal. For example, the resonant voltage meter 510 may include a rectifier 510-1 and a measured value provider 510-2.

For example, the rectifier 510-1 may be a half-wave rectifier configured by a combination of at least some of an operational amplifier A51, a plurality of resistors R51 and R52, and a plurality of diodes D51 and D52. Depending on the design, a voltage follower 515 may accurately transfer a voltage of the output terminal of the rectifier 510-1 to a comparator and error amplifier 530+540, form circuit directionality and insulation properties, and may be configured by a combination of at least some of an operational amplifier B, a resistor R53, and capacitor C51. For example, the measured value provider 510-2 may provide an output voltage of the rectifier 510-1 or the voltage follower 515 to the controller 300 and may include an operational amplifier C.

The target voltage provider 520 may be configured to provide a target voltage corresponding to a target amplitude to the comparator and error amplifier 530+540. Depending on the design, the target voltage provider 520 may provide a target voltage determined according to a target voltage determination signal received from the controller 300. The target voltage determination signal may correspond to mode information input by the user.

The comparator and error amplifier 530+540 may be configured to amplify a difference voltage between the voltage of the output terminal of the resonant voltage meter 510 and the target voltage. Accordingly, the regulator 500 may provide feedback the LC resonance based on the difference voltage. For example, the comparator and error amplifier 530+540 may be formed by a combination of at least some of the operational amplifier A53, the plurality of resistors R54 and R55, and the plurality of capacitors C52, C53, and C54. For example, the voltage follower 545 may be connected to the output terminal of the comparator and error amplifier 530+540 to accurately transfer the output voltage to the resonant voltage amplitude converter 550, may form circuit directionality and insulation properties, and may include an operational amplifier D.

The resonant voltage amplitude converter 550 may adjust the amplitude of the output of the waveform converter 600 according to a gain determined based on the amplitude of the LC resonance and the target amplitude, and transfer an output of the waveform converter 600 having the adjusted amplitude to at least one of the measurement terminal 100 and inductor 200.

For example, the resonant voltage amplitude converter 550 may be configured by a combination of at least some of the operational amplifier A55 and the plurality of resistors R56 and R57. A bias voltage V37 may be provided to the plurality of resistors R56 and R57. A voltage between the plurality of resistors R56 and R57 may be transferred to a first input terminal of the operational amplifier A55 and may be used as a reference voltage. The output voltage of the waveform converter 600 may be transferred to a second input terminal of the operational amplifier A55, and the output voltage of the comparator and error amplifier 530+540 may be used as a power source for the operational amplifier A55. Accordingly, the voltage at the output terminal of the operational amplifier A55 may be a voltage amplified from the output voltage of the waveform converter 600 according to a gain based on the output voltage of the comparator and error amplifier 530+540.

The output terminal of the resonant voltage amplitude converter 550 may be connected to a DC blocking capacitor CO2 or a load resistor R58, and an output voltage of the resonant voltage amplitude converter 550 may be used for feedback on the LC resonance of the inductor 200 and the measurement terminal 100 to which the capacitor component is connected. Accordingly, the regulator 500 may use the output of the waveform converter 600 for feedback on the LC resonance.

Referring to FIGS. 1 and 6, the apparatus 50in for measuring characteristics of a capacitor component according to an exemplary embodiment in the present disclosure may further include the waveform converter 600 electrically connected between the inductor 200 and the controller 300 and converting a waveform of the LC resonance.

The waveform converter 600 may be configured by a combination of at least some of a plurality of operational amplifiers A61 and A62, a plurality of resistors R61, R62, R63, R64, R65, R66, R67, and R68, and a plurality of capacitors C61 and C62, and may be provided with power V38, and an input terminal of the waveform converter 600 may be connected to a DC block capacitor C01.

For example, the waveform converter 600 may convert a sinusoidal waveform of the LC resonance into a pulse waveform. The pulse waveform may be more effective in controlling the amplitude for feedback on the LC resonance in the regulator 500.

Referring to FIGS. 1, 2, and 4, the apparatus 50in for measuring characteristics of a capacitor component according to an exemplary embodiment in the present disclosure may further include a DC voltage provider 400 providing a variable DC voltage to the measurement terminal 100.

The capacitance of the capacitor component CC may vary depending on an applied DC voltage. The apparatus 50in for measuring characteristics of a capacitor component may measure capacitance characteristics (DC-bias characteristics) according to a DC voltage applied to the capacitor component CC by measuring the capacitance of the capacitor component CC, while varying the DC voltage applied to the capacitor component CC.

In addition, since the apparatus 50in for measuring characteristics of a capacitor component may measure the capacitance based on the LC resonance, the influence of the DC voltage applied to the capacitor component CC on the capacitance measurement accuracy may be smaller than that of an RC resonance method. Therefore, the apparatus 50in for measuring characteristics of a capacitor component may accurately measure the DC-bias characteristics of the capacitor component CC.

For example, the DC voltage provider 400 may include at least some of a variable resistor 410, a voltage follower 420, a large-capacity capacitor 430, and a load resistor R42, and may be provided with power V39. The voltage provided from the variable resistor 410 to the voltage follower 420 may be determined based on a resistance values of the power V39 and the variable resistor 410, and may be applied accurately to the capacitor component CC by the voltage follower 420. The resistance value of the load resistor R42 may be determined based on load resistances R11 and R21 of the measurement terminal 100.

The large-capacity capacitor 430 may have a capacitance of 0.1 mF or more and may be electrically connected to the measurement terminal 100. Since the capacitance of the large-capacity capacitor 430 may be much larger than the capacitance of the capacitor component CC, an influence of a change in capacitance of the capacitor component CC on the DC voltage provided by the DC voltage provider 400 may decrease. Therefore, the apparatus 50in for measuring characteristics of a capacitor component may more accurately measure the DC-bias characteristics of the capacitor component CC. For example, the large-capacity capacitor 430 may be an electrolytic capacitor, may have a capacitance of 2.2 mF, and may be connected in series to the capacitor component CC.

Depending on the design, the apparatus 50in for measuring characteristics of a capacitor component may further include a DC voltage meter 450, and the DC voltage meter 450 may measure a DC voltage provided to the capacitor component CC by the DC voltage provider 400, and transfer a measurement result to the controller 300. The controller 300 may generate DC-bias characteristic information of the capacitor component CC based on the DC voltage measurement result and the measured capacitance information. For example, the DC voltage meter 450 may include a plurality of resistors R45 and R46, and resistance values of the plurality of resistors R45 and R46 may be determined based on the load resistors R11 and R21 of the measurement terminal 100.

The apparatus 50in for measuring characteristics of a capacitor component according to an exemplary embodiment in the present disclosure may include a boost DC-DC converter 390 boosting a voltage provided from a battery 380 or an external connection terminal 370. For example, the external connection terminal 370 may be a universal serial bus (USB) of another electronic device, and the battery 380 may be a secondary battery or an all-solid-state battery that may be used in a small electronic device and may be included in the apparatus 50in for measuring characteristics of a capacitor component.

Due to the boost DC-DC converter 390, a voltage provided from the battery 380 or the external connection terminal 370 may be a small voltage, such as 3.3V or 5V, and a DC voltage variable range (e.g., 0 V to 25 V) of the DC voltage provider 400 may be wide. Since the apparatus 50in for measuring characteristics of a capacitor component may receive a small voltage from the battery 380 or the external connection terminal 370, the apparatus 50in for measuring characteristics of a capacitor component be advantageously implemented as a portable device and may advantageously increase efficiency/convenience among performance of measuring characteristics of a capacitor component.

Referring to FIG. 7, an apparatus 50out for measuring characteristics of a capacitor component according to an exemplary embodiment in the present disclosure may include at least one of the measurement terminal 100, a jig 101, a first input unit 301, an output unit 330, the external connection terminal 370, and a second input unit 401, and may be implemented as a portable measurement device. In order to increase portability, a controller of the apparatus 50out for measuring characteristics of a capacitor component may be configured to generate only capacitance information among impedances of components connectable to the measurement terminal 100.

The measurement terminal 100 may include a cable 100a connected to the inductor and a probe 100b connected to the cable 100a, and the user may bring the probe 100b into contact with the capacitor component to measure the characteristics of the capacitor component.

The jig 101 may be configured to be coupled to the capacitor component. Accordingly, the portability of the apparatus 50out for measuring characteristics of a capacitor component may be further improved.

The first input unit 301 may transmit a mode input signal to the controller according to a user's touch. For example, the controller may convert an RMS voltage of LC resonance into 1 V or 0.5 V by changing a target amplitude when a mode input signal is input.

The output unit 330 may display characteristic information of the capacitor component output by the controller and may include a display panel. For example, an upper left region of the output unit 330 may display resonant frequency information, a lower left region of the output unit 330 may display capacitance information, an upper right region of the output unit 330 may display RMS voltage information of the LC resonance, and a lower right region of the output unit 330 may display DC voltage information applied to the capacitor component.

The external connection terminal 370 may be connected to other electronic devices (e.g., computers, portable terminals, home appliances, etc.) to receive power from the other electronic devices. For example, the external connection terminal 370 may be USB Type-C, and supplied power may be stored in a battery in the apparatus 50out for measuring characteristics of a capacitor component or may be boosted by a boost DC-DC converter.

The second input unit 401 may transmit a variable resistor resistance value adjustment signal to the controller according to a user's rotation. For example, the controller may adjust the resistance value of the variable resistor in the DC voltage provider when a variable resistor resistance value adjustment signal is input. Accordingly, the DC voltage applied to the capacitor component may be adjusted.

The apparatus for measuring characteristics of a capacitor component according to the present disclosure may improve performance (at least one of efficiency, convenience, accuracy, precision, and versatility) of measuring characteristics of a capacitor component.

While exemplary embodiments have been illustrated and described above, it will be apparent to those skilled in the art that modifications and variations could be made without departing from the scope of the present disclosure as defined by the appended claims.

What is claimed is:

1. An apparatus for measuring characteristics of a capacitor component, the apparatus comprising:
a measurement terminal configured to be connected to a capacitor component;
an inductor connected to the measurement terminal; and
a controller configured to generate characteristic information of the capacitor component based on LC resonance of the capacitor component and the inductor,
wherein the controller is configured to generate capacitance information of the capacitor component based on inductance and a resonant frequency of the LC resonance, and
the inductance is dependent on at least one of the resonant frequency and an amplitude of the LC resonance.

2. The apparatus of claim 1, wherein a rate of change of the inductance according to a change in the resonant frequency of the LC resonance varies depending on the resonant frequency.

3. The apparatus of claim 1, wherein the controller is configured to generate the capacitance information based on inductance according to an inductance determination method corresponding to a resonant frequency range to which the resonant frequency of the LC resonance belongs, among a plurality of predetermined resonant frequency ranges, and the resonant frequency.

4. The apparatus of claim 3, wherein sensitivity of the resonant frequency of the inductance determination method varies depending on the resonant frequency range to which the resonant frequency of the LC resonance belongs, among the plurality of resonant frequency ranges.

5. The apparatus of claim 3, wherein the controller is configured to generate the capacitance information based on an inductance constant corresponding to the resonant frequency range to which the resonant frequency of the LC resonance belongs, among the plurality of resonant frequency ranges, and the resonant frequency of the LC resonance.

6. The apparatus of claim 1, further comprising a DC voltage provider providing a variable DC voltage to the measurement terminal.

7. The apparatus of claim 6, wherein the DC voltage provider includes a capacitor having a capacitance of 0.1 mF or more and connected to the measurement terminal.

8. The apparatus of claim 6, wherein the DC voltage provider includes:
a boost DC-DC converter boosting a voltage supplied from a battery or an external source; and
a variable resistor connected to an output terminal of the boost DC-DC converter.

9. The apparatus of claim 1, wherein the controller is configured to generate only capacitance information among impedances of a component connectable to the measurement terminal.

10. The apparatus of claim 1, further comprising a jig configured to be coupled to the capacitor component.

11. The apparatus of claim 1, further comprising a regulator configured to feed back the LC resonance so that the amplitude of the LC resonance approaches a target amplitude.

12. An apparatus for measuring characteristics of a capacitor component, the apparatus comprising:
a measurement terminal configured to be connected to the capacitor component;
an inductor connected to the measurement terminal;
a controller configured to generate characteristic information of the capacitor component based on LC resonance of the capacitor component and the inductor; and
a regulator configured to feed back the LC resonance so that the amplitude of the LC resonance approaches a target amplitude.

13. The apparatus of claim 12, further comprising:
a waveform converter connected between the inductor and the controller and converting a waveform of the LC resonance,
wherein the regulator uses an output of the waveform converter for feedback on the LC resonance.

14. The apparatus of claim 13, wherein the regulator includes a resonant voltage amplitude converter configured to adjust an amplitude of the output of the waveform converter according to a gain determined based on the amplitude of the LC resonance and the target amplitude, and configured to output the output of the waveform converter having the adjusted amplitude to at least one of the measurement terminal and the inductor.

15. The apparatus of claim 12, wherein the regulator includes:
a resonant voltage meter having an input terminal connected to at least one of the measurement terminal and the inductor and configured to rectify an input signal;
a target voltage provider configured to provide a target voltage corresponding to the target amplitude; and
an error amplifier configured to amplify a difference voltage between a voltage of an output terminal of the resonant voltage meter and the target voltage,
wherein the regulator feeds back the LC resonance based on the difference voltage.

16. The apparatus of claim 12, further comprising a DC voltage provider providing a variable DC voltage to the measurement terminal.

17. The apparatus of claim 16, wherein the DC voltage provider includes a capacitor having a capacitance of 0.1 mF or more and connected to the measurement terminal.

18. The apparatus of claim 16, wherein the DC voltage provider includes:
a boost DC-DC converter boosting a voltage supplied from a battery or an external source; and
a variable resistor connected to an output terminal of the boost DC-DC converter.

19. The apparatus of claim 12, wherein the controller is configured to generate only capacitance information among impedances of a component connectable to the measurement terminal.

20. The apparatus of claim 12, further comprising a jig configured to be coupled to the capacitor component.

21. A method for measuring characteristics of a capacitor component, the method comprising:
obtaining LC resonance of the capacitor component and an inductor connected to the capacitor component in a measurement circuit;
obtaining an amplitude of the LC resonance and obtaining a resonant frequency of the LC resonance;
determining a range of a root mean square (RMS) voltage based on a measured value of the amplitude of the LC resonance;
determining inductance corresponding to the resonant frequency of inductance characteristics corresponding to the range of the RMS voltage; and
determining capacitance information based on the determined inductance.

22. The method of claim 21, further comprising connecting the capacitor component through a measurement terminal of the measurement circuit.

23. The method of claim 21, further comprising outputting the determined capacitance information of the capacitor component.

24. The method of claim 21, wherein the determining of the range of the RMS voltage includes: determining whether the RMS voltage falls within one of a first RMS voltage range, a second RMS voltage range, or a predetermined voltage range.

25. The method of claim 24, further comprising:
in response to a determination that the RMS voltage falls within the first RMS voltage range, determining the inductance corresponding to the resonant frequency of the inductance characteristics corresponding to the first RMS voltage range,
in response to a determination that the RMS voltage falls within the second RMS voltage range, determining the inductance corresponding to the resonant frequency of the inductance characteristics corresponding to the second RMS voltage range, and
in response to a determination that the RMS voltage does not fall within the predetermined RMS voltage range, determining that it is an error.

26. The method of claim 21, further comprising:
receiving mode information indicating characteristics of a material of the capacitor component,
wherein the RMS voltage range is determined according to the mode information.

27. An apparatus for measuring characteristics of a capacitor component, the apparatus comprising:
a processor; and
a non-transitory computer readable medium storing an algorithm, when executed by the processor, to cause the processor to:
obtain LC resonance of the capacitor component and an inductor connected to the capacitor component in a measurement circuit,
obtain an amplitude of the LC resonance and obtain a resonant frequency of the LC resonance,
determine a range of a root mean square (RMS) voltage based on a measured value of the amplitude of the LC resonance,
determine inductance corresponding to the resonant frequency of inductance characteristics corresponding to the range of the RMS voltage, and
determine capacitance information based on the determined inductance.

28. The apparatus of claim 27, wherein the algorithm, when executed by the processor, further causes the processor to: output the determined capacitance information of the capacitor component.

29. The apparatus of claim 27, wherein the algorithm, when executed by the processor, further causes the processor to: determine whether the RMS voltage falls within one of a first RMS voltage range, a second RMS voltage range, or a predetermined voltage range.

30. The apparatus of claim 29, wherein the algorithm, when executed by the processor, further causes the processor to:
in response to a determination that the RMS voltage falls within the first RMS voltage range, determine the inductance corresponding to the resonant frequency of the inductance characteristics corresponding to the first RMS voltage range,
in response to a determination that the RMS voltage falls within the second RMS voltage range, determine the inductance corresponding to the resonant frequency of the inductance characteristics corresponding to the second RMS voltage range, and
in response to a determination that the RMS voltage does not fall within the predetermined RMS voltage range, determine that it is an error.

31. The apparatus of claim 27, wherein the algorithm, when executed by the processor, further causes the processor to:
receive mode information indicating characteristics of a material of the capacitor component, and
determine the RMS voltage range according to the mode information.
